(19) United States
(12) Patent Application Publication
(10) Pub. No.: US 2010/0284211 A1
(43) Pub. Date: Nov. 11, 2010

(54) Multilevel Nonvolatile Memory via Dual Polarity Programming

(76) Inventor: Michael Hennessey, South Lyon, MI (US)

Correspondence Address: Kevin L. Bray;OVONYX, INC., 2956 Waterview Drive, Rochester Hills, MI, 48309, US

(21) Appl. No.: 12/435,741

(22) Filed: May 5, 2009

(51) Int. Cl. G11C 11/00; G11C 11/416

(52) U.S. Cl. 365/163; 365/148; 365/189.16

(57) ABSTRACT

A programming scheme and method of programming a non-volatile memory device for multilevel operation. The scheme includes defining two or more memory states, where at least one of the memory states is programmed with a positive polarity electrical pulse and at least one of the memory states is programmed with a negative polarity electrical pulse. The method includes programming with two or more pulses, where at least one pulse has positive polarity and one pulse has negative polarity. The non-volatile memory material may be a phase-change material and the two or more memory states may be distinguishable on the basis of electrical resistance.

### FIELD OF INVENTION

This invention relates to the programming of variable resistance memory materials. More particularly, this invention relates to the programming of phase-change memory materials for multilevel operation. Most particularly, this invention relates to a programming method utilizing positive and negative polarity pulses to define distinguishable memory states in a phase-change memory device.

### BACKGROUND OF THE INVENTION

Variable resistance materials are promising active materials for next-generation non-volatile electronic storage and computing devices. The central feature of a variable resistance material is its ability to adopt two or more distinguishable states that differ in electrical resistance. A variable resistance material can be programmed back and forth between the distinguishable states by providing energy or power. The applied energy or power induces an internal chemical, electronic, or physical transformation of the material that manifests itself as a measurable change in the resistance of the material. The different resistance states can be used as memory states to store or process data.

Phase change materials are a promising class of variable resistance materials. A phase change material is a material that is capable of undergoing a transformation, preferably reversible, between two or more distinct structural states. The distinct structural states may be distinguished on the basis of, for example, crystal structure, atomic arrangement, order or disorder, fractional crystallinity, relative proportions of two or more different structural states, or a physical (e.g. electrical, optical, magnetic, mechanical) or chemical property. In a common embodiment, the two or more distinct structural states include differing proportions of crystalline phase regions and amorphous phase regions of the phase change material, where the phase-change material is reversibly transformable between the different structural states. In the crystalline state, the phase change material has lower resistivity; while in the amorphous state, it has higher resistivity. Continuous variations in resistivity over a wide range can be achieved through control of the relative proportions of crystalline phase regions and amorphous phase regions in a volume of phase-change material. Reversibility of the transformations between structural states permits reuse of the material over multiple cycles of operation. In other embodiments, the two or more distinct structural states may include different proportions of several amorphous phases that differ in conductivity or different proportions of several crystalline phases that differ in conductivity, or combinations of any of the foregoing.

Typically, a variable resistance device is fabricated by placing the active variable resistance material, such as a phase change material, between two electrodes. Operation of the device occurs by providing an electrical signal between the two electrodes and across the active material. In a common application, phase-change materials may be used as the active material of a memory device, where distinct data values are associated with the different structural states and where each data value corresponds to a distinct resistance or resistivity of the phase-change material. The different structural states employed in memory operation may also be referred to herein as memory states or resistance states of the phase-change material. Write operations in a phase-change memory device, which may also be referred to herein as programming operations, apply electric pulses to the phase-change material to alter its structural state to a target state having the resistance associated with the intended data value. Read operations are performed by providing current or voltage signals across the two electrodes to measure the resistance. The energy of the read signal is sufficiently low to prevent disturbance of the state of the phase-change material.

Presently, most phase-change memory devices are operated in binary mode. In binary mode, the memory is operated between two structural states. To improve read margin and minimize read error, the two structural states for binary operation are normally selected to maximize the resistance contrast between the states. The range of resistance values of a phase-change material is bounded by a set state having a set resistance and a reset state having a reset resistance. The set state is a low resistance structural state whose electrical properties are controlled primarily by the more conductive (e.g. crystalline) portion of the phase-change material and the reset state is a high resistance structural state whose electrical properties are controlled primarily by the more resistive (e.g. amorphous) portion of the phase-change material. The set state and reset state are most commonly employed in binary operation and may be associated with the conventional binary “0” and “1” states.

In order to expand the commercial opportunities for phase-change memory, it is desirable to identify new phase-change compositions, device structures, and methods of programming that lead to improved performance. A key performance metric for memory devices is storage density, which is a measure of the amount of information that can be stored per unit area of memory material. Miniaturization is the most common strategy for increasing storage density. By shrinking the area required to store a bit of information, more bits can be stored in a memory chip of a given size. Miniaturization has been a successful strategy for increasing storage density over the past few decades, but is becoming increasingly more difficult to employ as fundamental size limits of manufacturability are reached.

An alternative approach for increasing storage density is to increase the number of bits stored in a given area of memory. Instead of reducing the area in which information is stored, more bits of information are stored in a particular area of memory. In conventional binary operation, only a single bit of information is stored in each memory location. Higher storage density can be achieved by increasing the storage capacity of each memory location. If two bits, for example, can be stored at each memory location, the storage capacity doubles without miniaturizing the memory location. In order to increase the storage capacity of each memory location, it is necessary for the memory material to be operable over more than the two states used in binary (single bit) operation. Two-bit operation, for example, requires a material that is operable over four distinguishable memory states.

Phase-change memory materials have the potential to provide multiple bit operation because of the wide resistance range that separates the set and reset states. In a typical phase-change memory device, the resistance of the set state is on the order of ˜1-10 kΩ, while the resistance of the reset state is on the order of ˜100−1000 kΩ. Since the structural states of a phase-change material are essentially continuously variable over the range of proportions of crystalline and amorphous phase volume fractions extending from the set state to the reset state, multiple bit memory operation at memory states having resistances intermediate between the set resistance and reset resistance is possible.

Although phase-change memory offers the potential for multiple bit operation, progress toward achieving a practical multilevel phase-change memory has been limited. One of the practical complications associated with multilevel phase-change operation is achieving adequate resolution of the different memory states with respect to a programming variable. Another practical complication is a need to achieve reproducible programming to targeted memory states. Reproducibility poses a particular challenge in the face of the normal variations in the programming conditions that accompany memory operation.

As phase-change memory is currently envisioned, different memory states are programmed by varying the applied current of fixed polarity electrical pulses. In order to achieve multilevel operation, it is desirable for the resistance of programmed memory states to be an appropriately sensitive function of programming current. If the programmed resistance is relatively insensitive to programming current, poor resolution of the programmed resistance occurs and the range of resistances available for memory states is compressed. If the programmed resistance is too sensitive to programming current, a large change in resistance occurs over a narrow range of current. In this situation, poor resolution of the programming current results as small fluctuations in programming current lead to large changes in resistance and it becomes difficult to unambiguously program memory states having intermediate resistance values.

Because of the focus on binary operation, limited attention has been paid in the prior art to strategies for enabling multilevel programming. In U.S. patent application Ser. No. 12/357,781, entitled “High Margin Multilevel Phase-change Memory via Pulse Width Programming” and filed Jan. 22, 2009, for example, the inventors described a programming method for controlling the sensitivity of programmed resistance to programming current that relied on programming pulse duration. The inventors showed that a particular change in resistance could be extended over a wider range of currents through a variable pulse width programming scheme. In doing so, the instant inventors demonstrated a reliable and reproducible method for achieving multilevel operation in a phase-change memory device.

In order to advance the commercial potential of phase-change memory, it is necessary to further develop phase-change materials, device structures or methods of operating phase-change memory devices that provide for reliable multilevel operation.

### SUMMARY OF THE INVENTION

The instant invention provides a method of programming non-volatile memory devices to achieve multilevel programming. The method is based on a programming scheme that employs programming pulses of opposite polarity. In the method, two or more memory states are defined, where at least one of the memory states is programmed with an electrical pulse having positive polarity and at least one of the memory states is programmed with an electrical pulse having negative polarity.

In a first embodiment, the programming scheme includes a memory state programmed by a positive polarity pulse and a memory state programmed by a negative polarity pulse. In a second embodiment, the programming scheme includes a memory state programmed by a positive polarity pulse, a memory state programmed by a high amplitude negative polarity pulse, and a memory state programmed by a low amplitude negative polarity pulse. In a third embodiment, the programming scheme includes a memory state programmed by a negative polarity pulse, a memory state programmed by a high amplitude positive polarity pulse, and a memory state programmed by a low amplitude positive polarity pulse. In a fourth embodiment, the programming scheme includes a memory state programmed by a high amplitude negative polarity pulse, a memory state programmed by a low amplitude negative polarity pulse, a memory state programmed by a high amplitude positive polarity pulse, and a memory state programmed by a low amplitude positive polarity pulse.

In one embodiment, the active material of the non-volatile memory device is a variable resistance material. In another embodiment, the active material of the non-volatile memory device is a phase-change material. In a further embodiment, the active material of the non-volatile memory device is a chalcogenide material.

### BRIEF DESCRIPTION OF THE DRAWINGS

FIG. 1 is an illustrative Resistance vs. Energy/Current plot for a phase-change material.

FIG. 2 depicts an illustrative assignment of resistance values to memory states of a multilevel memory device.

FIG. 3 illustrates the pulse shape of a representative set sweep pulse.

FIG. 4 depicts the structure of a representative phase-change memory device.

FIG. 5 shows the R-I characteristics of the phase-change device of FIG. 4 upon application of positive polarity pulses.

FIG. 6 shows the R-I characteristics of the phase-change device of FIG. 4 upon application of negative polarity pulses.

FIG. 7 illustrates a four-level programming scheme of the phase-change device of FIG. 4 that utilizes positive and negative polarity programming pulses.

FIG. 8 is a depiction of the I-V characteristics of a switching material that exhibits a transformation from a resistive state to a conductive state upon application of a threshold voltage.

### DETAILED DESCRIPTION OF THE ILLUSTRATED EMBODIMENTS

Although this invention will be described in terms of certain preferred embodiments, other embodiments that are apparent to those of ordinary skill in the art, including embodiments that do not provide all of the benefits and features set forth herein, are also within the scope of this invention. Accordingly, the scope of the invention is defined only by reference to the appended claims.

This invention is directed at a device and method for achieving multilevel programming capability in a non-volatile memory cell. The invention seeks to enlarge the number of accessible memory states by providing reproducible control over the mechanism underlying transformations between memory states. In one embodiment, the non-volatile memory material is a phase-change material and the underlying mechanism of operation is a structural transformation between amorphous and crystalline phases. In this embodiment, the instant invention provides reproducible control over the programmed resistance through control over the volume fractions of amorphous and crystalline phase regions and/or the spatial distribution of elements within the phase-change material.

In order to appreciate the benefits of the instant invention, it is helpful to review the basic operational characteristics of phase-change memory devices and to discuss issues that complicate the extension of phase-change memory to multilevel performance. The following discussion focuses on chalcogenide materials as illustrative phase-change materials. The basic principles apply equally to other forms of phase-change or state-change materials, such as pnictides or other classes of materials transformable between two or more states distinguishable on the basis of structure, a physical property or a chemical property.

Chalcogenide phase-change materials may also be referred to herein as chalcogenide memory materials or phase-change memory materials. Chalcogenide memory materials have been discussed in U.S. Pat. Nos. 5,166,758; 5,296,716; 5,534,711; 5,536,947; 5,596,522; and 6,087,674; the disclosures of which are hereby incorporated by reference.

An important feature of the operation of chalcogenide-based phase-change memory devices and arrays is the ability of the chalcogenide memory material to undergo a phase transformation between or among two or more structural states. The chalcogenide memory materials have structural states that include a crystalline state, one or more partially-crystalline states and an amorphous state. The crystalline state may be a single crystalline state or a polycrystalline state. The amorphous state may be a glassy state, vitreous state, or other state lacking long range structural order. A partially-crystalline state refers to a structural state in which a volume of chalcogenide or phase-change material includes an amorphous portion and a crystalline portion. Generally, a plurality of partially-crystalline states exists for the chalcogenide or phase-change material, where different partially-crystalline states may be distinguished on the basis of the relative proportion of amorphous and crystalline regions. Fractional crystallinity is one way to characterize the structural states of a chalcogenide phase-change material. The fractional crystallinity of the crystalline state is 100%, the fractional crystallinity of the amorphous state is 0%, and the fractional crystallinities of the partially-crystalline states may vary continuously between 0% (the amorphous limit) and 100% (the crystalline limit). Phase-change chalcogenide materials are thus generally able to transform among a plurality of structural states that may vary inclusively between fractional crystallinities of 0% and 100%.

Transformations among the structural states are induced by providing energy to the chalcogenide memory material. Energy in various forms can induce structural transformations of the crystalline and amorphous portions to alter the fractional crystallinity of a chalcogenide memory material. Suitable forms of energy include one or more of electrical energy, thermal energy, optical energy or other forms of energy (e.g. particle-beam energy) that induce electrical, thermal or optical effects in a chalcogenide memory material. Continuous and reversible variability of the fractional crystallinity is achievable by controlling the energy environment of a chalcogenide memory material. A crystalline state can be transformed to a partially-crystalline or an amorphous state, a partially-crystalline state can be transformed to a crystalline, amorphous or different partially-crystalline state, and an amorphous state can be transformed to a partially-crystalline or crystalline state through proper control of the energy environment of a chalcogenide memory material. Some considerations associated with the use of thermal, electrical and optical energy to induce structural transformations are presented in the following discussion.

The use of thermal energy to induce structural transformations exploits the thermodynamics and kinetics associated with the crystalline to amorphous or amorphous to crystalline phase transitions. An amorphous phase may be formed, for example, from a partially-crystalline or crystalline state by heating a chalcogenide material above its melting temperature and cooling at a rate sufficient to inhibit the formation of crystalline phases. A crystalline phase may be formed from an amorphous or partially-crystalline state, for example, by heating a chalcogenide material above the crystallization temperature for a sufficient period of time to effect nucleation and/or growth of crystalline domains. The crystallization temperature is below the melting temperature and corresponds to the minimum temperature at which crystallization may occur. The driving force for crystallization is typically thermodynamic in that the free energy of a crystalline or partially-crystalline state in many chalcogenide memory materials is lower than the free energy of an amorphous state so that the overall energy of a chalcogenide memory material decreases as the fractional crystallinity increases. Formation (nucleation and growth) of a crystalline state or crystalline domains within a partially-crystalline or amorphous state is kinetically enabled above the crystallization temperature, so that heating (even below the melting point) promotes crystallization by providing energy that facilitates the rearrangements of atoms needed to form a crystalline phase or domain. The fractional crystallinity of a partially-crystalline state can be controlled by controlling the temperature or time of heating or by controlling the temperature or rate of cooling of an amorphous or partially-crystalline state. Through proper control of the peak temperature, time of heating and rate of cooling, structural states over the full range of fractional crystallinity can be achieved for the chalcogenide phase-change materials.

The use of electrical energy to induce structural transformations relies on the application of electrical (current or voltage) pulses to a chalcogenide memory material. The mechanism of electrically-induced structural transformations is based on the Joule heating created by resistance of the material to current flow. Joule heating corresponds to a conversion of electrical energy to thermal energy and leads to an increase in the temperature of the chalcogenide material. By controlling the current density, the temperature can be increased to above the crystallization temperature, between the crystallization temperature and melting temperature, or above the melting temperature.

The crystalline phase portions of a chalcogenide memory material are sufficiently conductive to permit current densities that provide adequate Joule heating. The amorphous phase portions, however, are much less conductive and ordinarily would not support current densities sufficient to heat the material to the crystallization temperature or melting temperature. It turns out, however, that the amorphous phase of chalcogenide memory materials can be electrically switched to a highly conductive “dynamic” state upon application of a voltage greater than the threshold voltage. In the dynamic state, an amorphous phase region of a chalcogenide phase-change material can support a current density that is high enough to heat the material to or above the crystallization or melting temperature through Joule heating. As a result, nucleation and/or growth of a crystalline phase can be induced in an amorphous phase region. (For more information on electrical switching in chalcogenide materials see U.S. Pat. No. 6,967,344 entitled “Multi-Terminal Chalcogenide Switching Devices”.) By controlling the magnitude and/or duration of electrical pulses applied to a chalcogenide phase-change material, it is possible to continuously vary the fractional crystallinity through controlled interconversion of the crystalline and amorphous phases.

Joule heating produced in layers adjacent to the phase-change material may facilitate structural transformations. In many device designs, for example, resistive heaters in electrical communication with a phase-change material are located in close proximity to the phase-change material. The passage of current through a resistive heater produces thermal energy in the environment of the phase-change material that may be used to drive or aid structural transformations during programming.

The effect of electrical stimulation on a chalcogenide memory material is generally depicted in terms of the R-I (resistance-current) relationship of the material. The R-I relationship shows the variation of the programmed electrical resistance of a chalcogenide memory material as a function of the amount of electrical energy provided or as a function of the magnitude of the current or voltage pulse applied to a chalcogenide memory material. The R-I response is a convenient representation of the effect of crystalline-amorphous structural transformations on electrical resistance. A brief discussion of the R-I characteristics of chalcogenide memory materials follows.

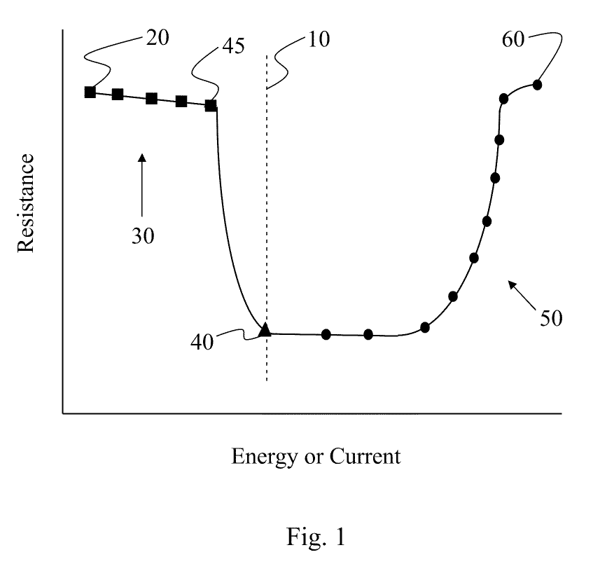

A representative depiction of the electrical resistance (Resistance) of a chalcogenide memory material as a function of electrical energy or current pulse magnitude (Energy/Current) is presented in the resistance plot shown in FIG. 1. The resistance plot includes two characteristic response regimes of a chalcogenide memory material to electrical energy. The regimes are approximately demarcated with the vertical dashed line 10 shown in FIG. 1. The regime to the left of the line 10 may be referred to as the accumulating regime of the memory material. The accumulation regime is distinguished by a nearly constant or gradually varying electrical resistance with increasing electrical energy that culminates in an abrupt decrease in resistance at a critical energy (which may be referred to herein as the set energy). The accumulation regime thus extends, in the direction of increasing energy, from the leftmost point 20 of the resistance plot, through a plateau region (generally depicted by 30) corresponding to the range of points over which the resistance variation is small or gradual to the set point or state 40 that follows an abrupt decrease in electrical resistance. Plateau 30 may be horizontal or sloping.

The left side of the resistance plot is referred to as the accumulating regime because the structural state of the chalcogenide material cumulatively evolves as energy is applied. More specifically, the fractional crystallinity of the structural state increases with the total applied energy so that the material “accumulates” crystalline phase content in this regime. The leftmost point 20 corresponds to the structural state in the accumulating regime having the lowest fractional crystallinity and may be referred to as the reset state. This state may be fully amorphous or may be primarily amorphous with some degree of crystalline content. As energy is added, the chalcogenide material progresses among a plurality of partially-crystalline states with increasing fractional crystallinity along plateau 30 as crystalline phase regions accumulate in the material. Selected accumulation states (structural states in the accumulation region) are marked with squares in FIG. 1.

Upon accumulation of a sufficient amount of crystalline phase content, the fractional crystallinity of the chalcogenide memory material increases sufficiently to effect a setting transformation. The setting transformation is characterized by a dramatic decrease in electrical resistance and culminates in stabilization of set state 40. The structural states in the accumulation regime may be referred to as accumulation states of the chalcogenide memory material. Structural transformations in the accumulating regime are unidirectional in that they progress in the direction of increasing applied energy within plateau region 30 and are reversible only by first driving the chalcogenide material through the set point 40 and the reset point 60, resetting the device. Once the reset state is obtained, lower amplitude current pulses can be applied and the accumulation response of the chalcogenide material can be restored.

The addition of energy to a chalcogenide material in the accumulating regime is believed to lead to an increase in fractional crystallinity through the formation of new crystalline domains, growth of existing crystalline domains or a combination thereof. It is believed that the electrical resistance varies only gradually along plateau 30 despite the increase in fractional crystallinity because the crystalline domains form or grow in relative isolation of each other so as to prevent the formation of a contiguous crystalline network that spans the chalcogenide material between the two electrodes of the memory device. This type of crystallization may be referred to herein as sub-percolation crystallization.

In one model, the setting transformation coincides with a percolation event in which a contiguous, interconnected crystalline network forms within the chalcogenide material, where the network bridges the space between the two electrodes of the device. Such a network may form, for example, when crystalline domains increase sufficiently in size to impinge upon neighboring domains. Since the crystalline phase of chalcogenide materials is more conductive than the amorphous phase, the percolation event corresponds to the formation of a contiguous conductive pathway through the chalcogenide material. As a result, the percolation event is marked by a dramatic decrease in the resistance of the chalcogenide material, where the resistance of the material following the percolation event depends on the effective area of the percolation path. The leftmost point 20 of the accumulation regime may be an amorphous state or a partially-crystalline state lacking a contiguous crystalline network. Sub-percolation crystallization commences with an initial amorphous or partially-crystalline state and progresses through a plurality of partially-crystalline states having increasingly higher fractional crystallinities until the percolation threshold is reached and the setting transformation occurs.

The regime to the right of the line 10 of FIG. 1 may be referred to as the direct overwrite regime. The direct overwrite regime extends from set state 40 through a plurality of intermediate states (generally depicted by 50) to a reset point or state 60. The various points in the direct overwrite regime may be referred to as direct overwrite states of the chalcogenide memory material. Selected direct overwrite states are marked with circles in FIG. 1. Structural transformations in the direct overwrite regime may be induced by applying an electric current or voltage pulse to a chalcogenide material. In FIG. 1, an electric current pulse is indicated.

In the direct overwrite regime, the resistance of the chalcogenide memory material varies with the magnitude of the applied electric pulse. The resistance of a particular direct overwrite state is characteristic of the structural state of the chalcogenide memory material, and the structural state is dictated by the magnitude of the applied current pulse. The fractional crystallinity of the chalcogenide memory material decreases as the magnitude of the current pulse increases. The fractional crystallinity is highest for direct overwrite states at or near set point 40 and progressively decreases as reset state 60 is approached. The chalcogenide memory material transforms from a structural state possessing a contiguous crystalline network at set state 40 to a structural state that is amorphous or substantially amorphous or partially-crystalline without a contiguous crystalline network at reset state 60. The application of current pulses having increasing magnitude has the effect of converting portions of the crystalline network into an amorphous phase and ultimately leads to a disruption or interruption of contiguous high-conductivity crystalline pathways in the chalcogenide memory material. As a result, the resistance of the chalcogenide memory material increases with increasing applied current in the direct overwrite region.

In contrast to the accumulating region, structural transformations in the direct overwrite region are reversible and bi-directional. As indicated hereinabove, each state in the direct overwrite region may be identified by its resistance and an associated current pulse magnitude, where application of the associated current pulse magnitude induces changes in fractional crystallinity that produce the particular resistance state. Application of a subsequent current pulse may increase or decrease the fractional crystallinity of an existing resistance state of the chalcogenide memory material. If the subsequent current pulse has a higher magnitude than the pulse used to establish the existing state, the fractional crystallinity of the chalcogenide memory material decreases and the structural state is transformed from the existing state in the direction of the reset state along the direct overwrite resistance curve. Similarly, if the subsequent current pulse has a lower magnitude than the pulse used to establish the existing state, the fractional crystallinity of the chalcogenide memory material increases and the structural state is transformed from the existing state in the direction of the set state along the direct overwrite resistance curve.

The direct overwrite states of the chalcogenide memory material may be used to define memory states of a memory device. Most commonly, the memory devices are binary memory devices that utilize two of the direct overwrite states as memory states, where a distinct data value (e.g. “0” or “1”) is associated with each state. Each binary memory state corresponds to a distinct structural state of the chalcogenide material. Readout or identification of the state can be accomplished by measuring the resistance of the material (or device) since each structural state is characterized by a distinct resistance value. The operation of transforming a chalcogenide memory material to the structural state associated with a particular memory state may be referred to herein as programming the chalcogenide memory material, writing to the chalcogenide memory material or storing information in the chalcogenide memory material. The resistance of the memory state established by programming the chalcogenide memory material may also be referred to herein as the programmed resistivity of the material or programmed resistance of the device.

To facilitate readout and minimize reading errors, it is desirable to select the memory states of a binary memory device so that the contrast in resistance of the two states is large. Typically the set state (or a state near the set state) and the reset state (or a state near the reset state) are selected as memory states in a binary memory application. The resistance contrast depends on details such as the chemical composition of the chalcogenide, the thickness of the chalcogenide material in the device and the geometry of the device. For a layer of phase-change material having the composition Ge₂₂Sb₂₂Te₅₆, a thickness of ˜600 Å, and pore diameter of below ˜0.1 μm in a typical two-terminal device geometry, for example, the resistance of the reset state is ˜100-1000 kΩ and the resistance of the set state is under ˜10 kΩ. Phase-change devices in general show resistances in the range of ˜100 kΩ to ˜1000 kΩ in the reset state and resistance of ˜0.5 kΩ to ˜50 kΩ in the set state. In the preferred phase-change devices, the resistance of the reset state is at least a factor of two, and more typically an order of magnitude or more, greater than the resistance of the set state.

Representative compositions of chalcogenide phase-change materials have been discussed in U.S. Pat. Nos. 5,543,737; 5,694,146; 5,757,446; 5,166,758; 5,296,716; 5,534,711; 5,536,947; 5,596,522; and 6,087,674; the disclosures of which are hereby incorporated by reference in their entirety herein. The chalcogenide phase-change materials generally include one or more elements from column VI of the periodic table (the chalcogen elements) and optionally one or more chemical modifiers from columns III, IV or V. One or more of S, Se, and Te are the most common chalcogen elements included in a chalcogenide phase-change material. Suitable modifiers include one or more of trivalent and tetravalent modifying elements such as As, Ge, Ga, Si, Sn, Pb, Al, Sb, In, and Bi. Transition metals such as Cu, Ni, Zn, Ag, and Cd may also be used as modifiers. A preferred chalcogenide composition includes one or more chalcogenide elements along with one or more trivalent or tetravalent modifiers and/or one or more transition metal modifiers. Materials that include Ge, Sb, and/or Te, such as Ge₂Sb₂Te₅, are examples of chalcogenide phase-change materials in accordance with the instant invention. Other examples of phase-change materials include, but are not limited to, GaSb, InSb, InSe, Sb₂Te₃, GeTe, Ge₂Sb₂Te₅, ternary Ge—Sb—Te compositions, InSbTe, ternary In—Sb—Te compositions, ternary GaSeTe compositions, TAG and other ternary Te—As—Ge compositions, GaSeTe, SnSb₂Te₄, InSbGe, ternary In—Sb—Ge compositions, AgInSbTe, quaternary Ag—In—Sb—Te compositions, (GeSn)SbTe, quaternary Ge—Sn—Sb—Te compositions, GeSb(SeTe), quaternary Ge—Sb—Se—Te compositions, and Te₈₁Ge₁₅Sb₂S₂ and quaternary Te—Ge—Sb—S compositions. U.S. Pre-Grant Pub. 20070034850 and U.S. Pat. No. 7,525,117, the disclosures of which are hereby incorporated by reference in their entirety, disclose phase-change materials having reduced Ge and/or Te content.

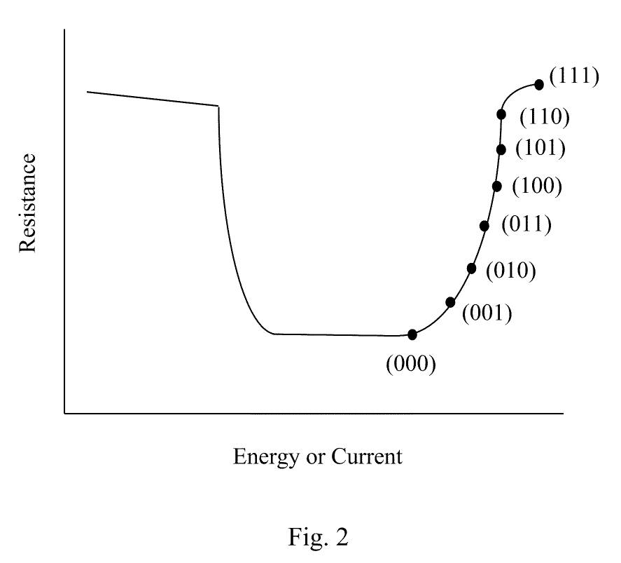

This invention seeks to extend the applicability of chalcogenide memory materials beyond binary (single bit) memory applications to multilevel (non-binary or multiple bit) memory applications. The storage density of a multilevel chalcogenide memory device improves as the number of memory states increases. As described hereinabove, the direct overwrite region of the resistance plot of a chalcogenide or phase-change material includes a plurality of states that differ in resistance over a resistance interval extending from the set state to the reset state. Multilevel memory operation can be achieved by selecting three or more states from among the direct overwrite states and associating a unique data value with each. Each of the three or more states corresponds to a distinct structural state of the chalcogenide and is characterized by a distinct resistance value. Two bit operation can be achieved by selecting four direct overwrite states to serve as memory states, three bit operation can be achieved by selecting eight direct overwrite states to serve as memory states, etc. FIG. 2 shows an illustrative selection of eight direct overwrite states for use as memory states in a three-bit memory device. One assignment of data values to the different states is also shown, where the (000) state corresponds to the set state, the (111) state corresponds to the reset state, and a series of intermediate resistance states is included.

To improve the storage density in a multilevel memory device, it is desirable to operate the memory material over as many states as possible. The number of memory states is controlled by the resistance interval between the set state and reset state, the resolution limit of the resistance measurement performed during the read operation, the stability of the resistance values, and the sensitivity of programmed resistance to programming conditions. A large resistance difference between the set and reset states provides a wide dynamic range of resistance over which operation of the memory device can occur. The resolution limit of the read resistance measurement imposes a practical limit on the spacing of resistance values associated with the different memory states. The resolution limit depends on read noise and read circuit limitations. The resistance differential between adjacent memory states must be greater than the resolution of the read resistance measurement. Stable resistance values are needed to insure that programmed resistance values do not vary (drift) in time.

This invention is concerned with a method of programming non-volatile memory devices for multilevel operation. The method includes using electrical pulses of opposite polarity to program a non-volatile memory material. The programming scheme includes a series of distinguishable memory states, where at least one state is programmed with a negative polarity pulse and at least one state is programmed with a positive polarity pulse. The pulses may be of the same or different amplitude and may be of the same or different duration. The shape or profile of the negative and positive polarity pulses may be the same or different as well.

In a first embodiment, the programming scheme includes a memory state programmed by a positive polarity pulse and a memory state programmed by a negative polarity pulse. The positive polarity pulse may have a greater, lesser, or the same amplitude as the negative polarity pulse. The positive polarity pulse may also have a greater, lesser, or the same duration as the negative polarity pulse. The positive polarity pulse may further have the same or different shape or profile as the negative polarity pulse.

In a second embodiment, the programming scheme includes a memory state programmed by a positive polarity pulse, a memory state programmed by a high amplitude negative polarity pulse, and a memory state programmed by a low amplitude negative polarity pulse. In a related embodiment, the programming scheme includes a memory state programmed by a positive polarity pulse, a memory state programmed by a long duration negative polarity pulse, and a memory state programmed by a short duration negative polarity pulse.

In a third embodiment, the programming scheme includes a memory state programmed by a negative polarity pulse, a memory state programmed by a high amplitude positive polarity pulse, and a memory state programmed by a low amplitude positive polarity pulse. In a related embodiment, the programming scheme includes a memory state programmed by a negative polarity pulse, a memory state programmed by a long duration positive polarity pulse, and a memory state programmed by a short duration positive polarity pulse.

In a fourth embodiment, the programming scheme includes a memory state programmed by a high amplitude negative polarity pulse, a memory state programmed by a low amplitude negative polarity pulse, a memory state programmed by a high amplitude positive polarity pulse, and a memory state programmed by a low amplitude positive polarity pulse. In a related embodiment, the programming scheme includes a memory state programmed by a long duration negative polarity pulse, a memory state programmed by a short duration negative polarity pulse, a memory state programmed by a long duration positive polarity pulse, and a memory state programmed by a short duration positive polarity pulse.

In further embodiments, one or more positive polarity pulses are combined with one or more negative polarity pulses to define a series of distinguishable memory states, where the amplitudes and/or durations of the different pulses encompass any combination of positive pulse magnitude relative to negative pulse magnitude.

In a representative non-volatile memory device, the active non-volatile memory material is a phase-change material. In one embodiment, the positive polarity pulse is a reset pulse and the negative polarity pulse is a set pulse. In another embodiment, the positive polarity pulse is a set pulse and the negative polarity pulse is a reset pulse. The set and reset pulses generally have a leading edge in which pulse amplitude ramps up, a peak amplitude, and a falling edge in which pulse amplitude ramps down. The leading edge and falling edge exist over a specified fixed or variable window of time and generally control the rate of heating or cooling of the phase-change material. The time window over which the peak amplitude persists may be controlled. Illustrative pulse shapes include square wave pulses, pulses with linear leading edges, pulses with linear falling edges, and pulses having a trapezoidal or triangular waveform.

A set pulse is an electrical pulse capable of transforming the phase-change material to a set state. A set pulse generally has sufficient energy to heat at least a portion of the phase-change material to a temperature at or above the crystallization temperature. In one embodiment, the set pulse heats the phase-change material to a temperature between the crystallization temperature and the melting temperature and has a duration sufficient to induce the crystallization needed to set the material. In another embodiment, the set pulse heats the phase-change material to a temperature above the melting temperature and the ramp down or falling edge of the pulse is extended in time to controllably cool the material. As pulse amplitude decreases along the falling edge of the pulse, the temperature of the phase-change material decreases. By controlling the rate of decrease of pulse amplitude, the temperature of the material can be controlled. If the phase-change material is controlled to exist at a temperature between the crystallization temperature and melting temperature for a sufficiently long period of time, crystallization can be induced and the degree of crystallinity can be controlled to achieve a set state or other structural state possessing crystalline content.

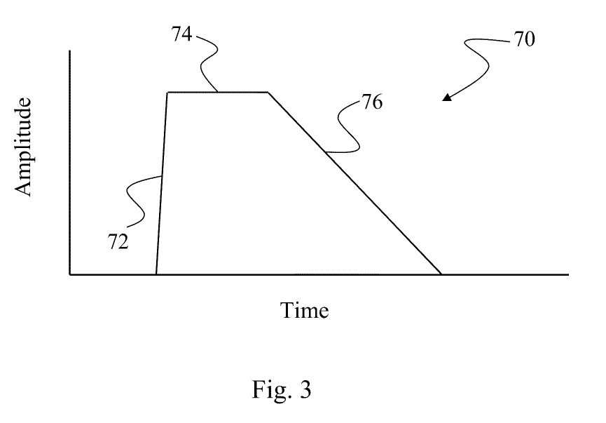

In one embodiment, the set pulse is a set sweep. In a set sweep, the peak pulse amplitude is sufficient to heat the phase-change material to a temperature above the melting temperature and the falling edge of the set pulse persists over a sufficiently long period of time to permit crystallization. A set sweep pulse has a generally triangular or trapezoidal appearance when depicted in graphical form as pulse amplitude as a function of pulse time. A schematic depiction of a set sweep pulse having positive polarity is presented in FIG. 3. Set sweep pulse 70 has leading edge 72, plateau 74, and falling edge 76, where falling edge 76 evolves more slowly in time than leading edge 72. Other embodiments of set sweep pulses and advantages associated with set sweep pulse are described in U.S. Pat. Nos. 6,570,784 and 6,687,153, the disclosures of which are incorporated by reference herein.

A reset pulse is an electrical pulse that decreases the crystalline phase volume fraction of the phase-change material and renders it more amorphous. A reset pulse delivers sufficient energy to the phase-change material to heat to at least the melting temperature and includes a falling edge that is sufficiently short in duration to inhibit crystallization. A fast ramp down in temperature promotes establishment of amorphous phase content by cooling the phase-change material to a temperature below the crystallization temperature sufficiently quickly to prevent significant crystallization. The reset state established by a reset pulse is a high resistance, primarily amorphous structural state of the phase-change material.

In another embodiment, programming includes a positive polarity pulse as a set pulse and a negative polarity pulse that programs a phase-change device to a memory state having a resistance intermediate between the set resistance and reset resistance of the device. In a related embodiment, programming includes a positive polarity pulse as a reset pulse and a negative polarity pulse that programs a phase-change device to a memory state having a resistance intermediate between the set resistance and reset resistance of the device.

In still another embodiment, programming includes a negative polarity pulse as a set pulse and a positive polarity pulse that programs a phase-change device to a memory state having a resistance intermediate between the set resistance and reset resistance of the device. In a related embodiment, programming includes a negative polarity pulse as a reset pulse and a positive polarity pulse that programs a phase-change device to a memory state having a resistance intermediate between the set resistance and reset resistance of the device.

In a further embodiment, programming includes a negative polarity pulse that programs a phase-change device to a memory state having a resistance intermediate between the set resistance and reset resistance of the device and a positive polarity pulse that programs a phase-change device to a memory state having a resistance intermediate between the set resistance and reset resistance of the device.

### EXAMPLE

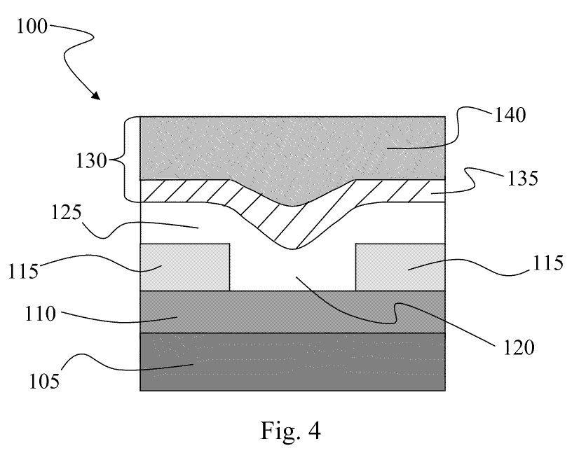

In this example, the response of a representative non-volatile memory device to programming with opposite polarity pulses is presented. The non-volatile memory device is a phase-change memory device that includes a chalcogenide material having the composition Ge₂Sb₂Te₅ as the active material. A depiction of the device structure used in this example is shown in FIG. 4. Device 100 includes substrate 105, lower electrode 110, and dielectric 115. Dielectric 115 includes an opening 120 in which phase-change material 125 is formed. Upper electrode 130 is formed over active phase-change material 125 and includes carbon layer 135 and molybdenum nitride layer 140. Lower electrode 110 is formed from titanium aluminum nitride and dielectric 115 is an oxide layer. Phase-change material 125 has the composition Ge₂Sb₂Te₅ and was prepared by sputtering. Lower electrode 110, dielectric 115, and carbon layer 135 had thicknesses of 45-50 nm. Molybdenum nitride layer 140 had a thickness of ˜200 nm and phase-change material 125 had a thickness of ˜25 nm.

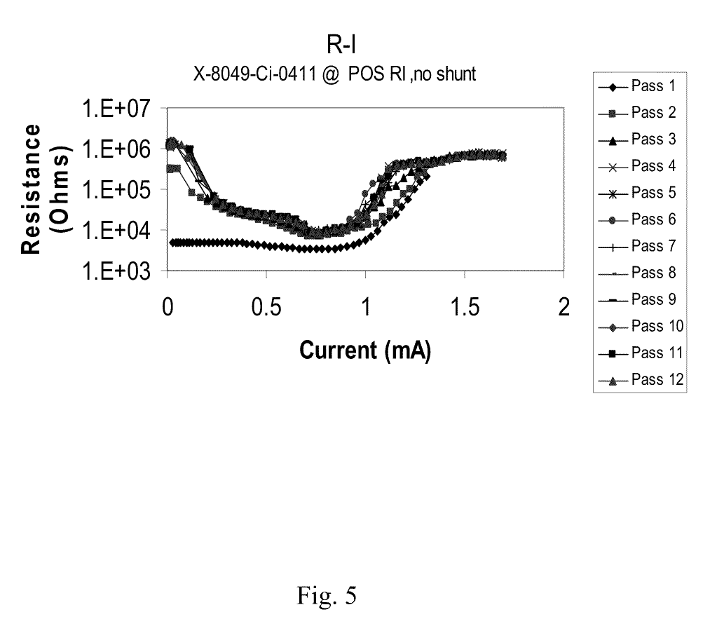

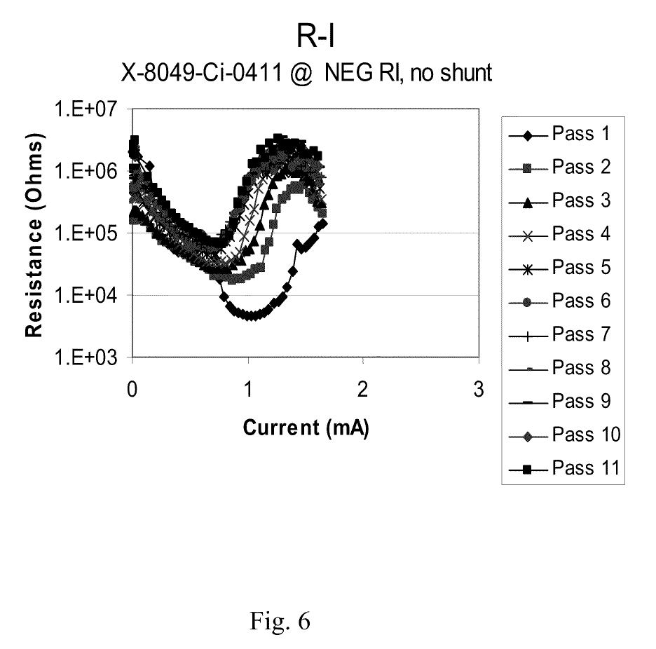

FIGS. 5 and 6 show the R-I characteristics of device 100. As indicated hereinabove, the R-I plot represents the dependence of device resistance on the amplitude of current pulses applied to the device. To obtain the R-I plot, a series of R-I traces over several cycles of operation was obtained. For each R-I trace, a series of 50 voltage pulses of fixed duration (500 ns) and increasing amplitude were applied to the device. For each trace, a voltage amplitude range extending from 0V to a maximum voltage was selected and a voltage increment for the individual pulses of the series of applies pulses was established by dividing the maximum voltage by 50. The individual pulses within the series of applied pulses were separated by the voltage increment and the R-I trace was obtained beginning with the smallest amplitude pulse and continuing until a pulse having the maximum voltage amplitude was applied. For each pulse, the current passing through the device was measured and the resistance of the device was determined. From this data, the dependence of resistance on current amplitude was obtained. The procedure was repeated to obtain R-I traces for several cycles of operation. The maximum voltage for the first cycle of operation was 4 V, the maximum voltage for the second cycle of operation was 4.5 V, and the maximum voltage for subsequent cycles of operation was 5 V.

For purposes of this example, positive polarity corresponds to a voltage difference across the device in which upper electrode 130 is positive relative to lower electrode 110. When a positive polarity pulse is applied, electrons flow from lower electrode 110 to upper electrode 130. Negative polarity corresponds to a voltage difference across the device in which upper electrode 130 is negative relative to lower electrode 110. When a negative polarity pulse is applied, electrons flow from upper electrode 130 to lower electrode 110.

FIG. 5 shows the R-I characteristics of the device upon application of positive polarity pulses. Results for 12 cycles of operation are shown. The initial cycle (“pass 1”, filled diamond symbols) was performed on an as-fabricated device. The as-fabricated device had a virgin resistance of ˜5 kΩ. The resistance remained nearly constant with increasing current up to ˜0.9 mA. As the current exceeded 0.9 mA, the device resistance increased dramatically and eventually reached ˜200 kΩ upon application of a 4V pulse. The behavior for subsequent cycles of operation indicates that with positive polarity pulses, the device had a reset resistance in the range from ˜600 kΩ to ˜800 kΩ and that the device transformed to a set state having a resistance of ˜8-10 kΩ at a current of ˜0.75 mA. [ 0 0 6 5 ] After completing several cycles of operation with positive polarity pulses, the device was subjected to testing with negative polarity pulses over 11 cycles of operation. For negative polarity cycling, voltage pulses separated by approximately 0.1V were applied over the range 0V-5V. The R-I results obtained for negative polarity cycling are shown in FIG. 6. The data trace depicted with filled diamond symbols corresponds to the first cycle of operation with negative pulses. The data trace for the first cycle of operation showed a lower set resistance and a displacement to higher current than data traces for subsequent cycles of operation as device performance stabilized. Stabilized data obtained from programming the device with negative polarity pulses indicated that the reset resistance was ˜1-3 MΩ and that the set resistance was ˜40-70 kΩ.

The R-I results generally indicate that the reset state resistance and set state resistance are both higher when the device is programmed with negative polarity pulses than when the device is programmed with positive polarity pulses. The set and reset resistances for negative and positive pulses are well-resolved and may be used to define a multilevel scheme of memory states. In one embodiment, a four level scheme of programming states may be envisioned where a first state is programmed with a positive polarity set pulse, a second state is programmed with a negative polarity set pulse, a third state is programmed with a positive polarity reset pulse, and a fourth state is programmed with a negative polarity reset pulse.

As noted above, a multilevel programming scheme utilizing positive and negative polarity pulses may include pulses having characteristics intermediate between set and reset pulses. The instant dual polarity multilevel programming scheme generally contemplates three or more programming states in which at least one state is programmed with a negative polarity pulse and at least one state is programmed with a positive polarity pulse. For the negative and positive polarity programming pulses, pulse parameters such as voltage, duration, risetime and falltime may be defined differently for each programming state and may be defined differently for positive and negative polarity pulses. A positive polarity reset programming pulse, for example, may have the same (aside from polarity) or different pulse waveform than a negative polarity reset programming pulse and likewise for positive and negative polarity set programming pulses.

The number of positive polarity programming pulses may be the same as or different from the number of negative polarity programming pulses used in the programming scheme. In one embodiment, one programming state may be obtained with a negative polarity pulse and two or more or all other programming states may be obtained with positive polarity pulses. A four-level programming scheme may, for example, include three states programmed with positive polarity pulses and one state programmed with a negative polarity pulse. Alternatively, a four-level programming scheme may include two programming states programmed with positive polarity pulses and two programming states programmed with negative polarity pulses. As a further possibility, a four-level programming scheme may include three states programmed with negative polarity pulses and one state programmed with a positive polarity pulse.

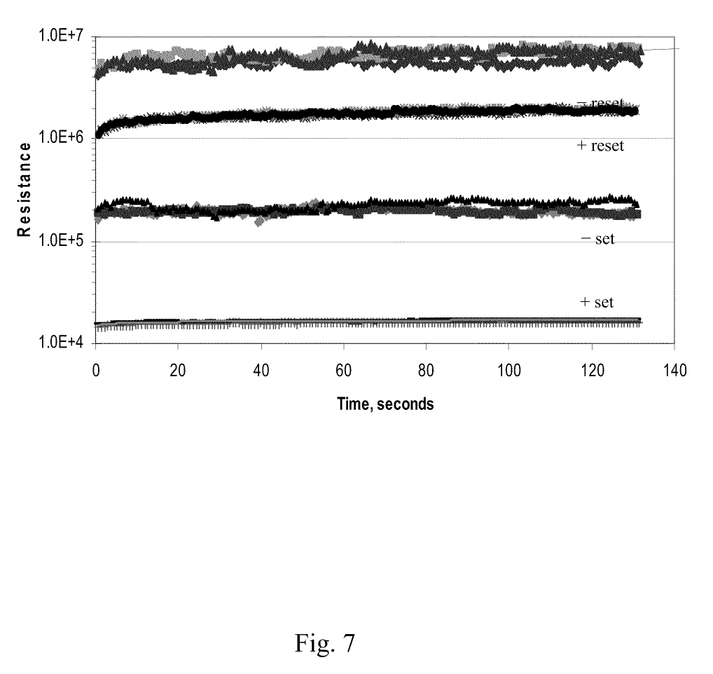

FIG. 7 presents data illustrating the performance of one example of a four-level programming scheme that utilizes two positive polarity pulses and two negative polarity pulses. Each of the pulses had a duration of 500 ns, a risetime of 3 ns and a falltime of 3 ns. The pulses are labeled “−reset” (negative reset), “+reset” (positive reset), “−set” (negative set), “+set” (positive set) in FIG. 7. The negative reset pulse had an amplitude of 4V, the positive reset pulse had an amplitude of 5V, the negative set pulse had an amplitude of 2.5V, and the positive set pulse had an amplitude of 2.5V.

FIG. 7 shows the resistance of each of the four states upon initial programming and the drift in resistance over time for each of the four states. The resistance at zero time corresponds to the resistance of each state immediately after programming. Each state was programmed in three separate trials and data is shown for each state for each trial. The results indicate: (1) the negative polarity reset state has an initial resistance of ˜4.5 MΩ; (2) the positive polarity reset state has an initial resistance of ˜1.1 MΩ; (3) the negative polarity set state has an initial resistance of ˜180 kΩ; and (4) the positive polarity set state has a resistance of ˜15 kΩ. The four states remain well-resolved and drift only slightly in resistance over time.

The results of FIG. 7 show that programming pulses that differ in polarity, but are otherwise the same, may produce programmed states that differ in resistance and may lead to distinct, well-resolved programming states for multilevel operation. Negative and positive polarity set pulses used in the data of FIG. 7 are equal in voltage magnitude and time characteristics and yet provide different programmed resistances. The different limiting reset resistances obtained for positive and negative polarity reset pulses having equal amplitudes of 5V and equal durations of 500 ns in the R-I traces of FIGS. 5 and 6 show a corresponding result for reset pulses. The ability to achieve three or more resistance levels corresponding to limiting or saturated states simplifies multi-level programming and improves the accuracy with which these levels can be placed.

While not wishing to be bound by theory, the instant inventor offers a possible explanation of the difference in programmed resistance induced by pulses of opposite polarity that have otherwise equivalent characteristics. Phase-change materials are multi-element materials that oftentimes have the ability to form multiple structural phases that differ in the relative proportion of constituent elements. Phase segregation, for example, is believed to be a contributing factor to device failure upon repeated cycling for some phase-change materials. Phase segregation can entail a progressive stabilization of materials having alternative stoichiometries from the constituent elements to produce new phases and/or a mixed phase system. Phase segregation may also entail a reorganization of the programming volume in which amorphous phase regions become physically separated from crystalline phase regions. The primary consequence of phase segregation is a transformation of the phase-change material from an initially spatially and compositionally homogeneous state to a state that is heterogeneous or non-uniform with respect to one or more of structural phase, crystal phase, and/or element distribution.

A prelude to non-uniformity in composition or structure is atomic migration. In order for atoms to organize into alternative stoichiometric compositions or alternative structural or crystallographic phases, there must be a driving force for atomic migration. Different atoms must be able to move within the volume of phase-change material relative to each other in order to alter the spatial distribution of atoms needed to enable structural or compositional reorganization. Electromigration is an important atomic transport mechanism in electrically-driven systems. Electromigration is an electric field induced migration of atoms. Because of differences in charge, charge density, or interatomic interactions, atoms of different chemical elements respond differently to an applied electric field. In electrical phase-change devices, programming occurs by positioning a phase-change material between two (or more) electrodes and applying a voltage between the electrodes. The voltage establishes an electric field within the phase-change volume and renders one electrode positive relative to another electrode.

It is believed by the instant inventor that the electric field used to operate the instant devices induces a separation or relative migration of constituent elements within the phase-change material of the instant devices to produce a compositional or structural non-uniformity on at least a local scale. The harsh thermal environment experienced by the phase-change material during programming is believed to facilitate electromigration. As indicated hereinabove, programming of a phase-change material to increase resistance in the direct overwrite region requires delivery of electrical energy to produce Joule heating in an amount sufficient to heat the phase-change material to or above the melting point. In the molten phase, the phase-change material is more fluid and atoms become more mobile. As atoms become more mobile and less confined by a rigid solid structure, they are more susceptible to electromigration. Even in the absence of melting, electromigration is believed to occur. Transformation of a phase-change material from an amorphous phase to a crystalline phase can occur by heating the material to a temperature above the crystallization temperature and maintaining the temperature for a sufficiently long period of time. Although the crystallization temperature is below the melting temperature, it is nonetheless an elevated temperature that provides thermal assistance to the tendency of an electric field to induce atomic migration. In order to crystallize from an amorphous phase, atoms must rearrange. The conditions present during crystallization thus correspond to a sufficiently high mobility regime to permit atomic transport. The additional application of an electric field provides a further driving force for atomic motion.

In the context of the instant invention, it is proposed that negative and positive polarity pulses are capable of inducing an electromigration of atomic constituents of the phase-change material. As electromigration occurs, the spatial distribution of atoms is altered and it is believed that the resulting local alterations in composition or structure influence the resistance of the phase-change material. The results shown in FIG. 7 suggest that the alterations in composition or structure induced by electromigration differ for positive and negative polarity pulses and vary with pulse characteristics such as pulse duration, amplitude or profile. The data indicate that for otherwise equivalent pulse characteristics, negative polarity pulses consistently program the phase-change device to a state having higher resistance than positive polarity pulses. The alloy composition used in this example (GST 225) was initially developed for use in binary memory applications. It is believed that alloys specifically designed to take advantage of material migration effects will extend the utility of this approach. Additionally, device geometry may be optimized to maximize the difference between saturated set and saturated reset resistance when programmed with positive and negative polarity.

A plurality of phase-change devices may be configured as an array. In a typical array, a series combination of a phase-change device and an access device interconnects a word line and a bit line. The array includes a plurality of word lines and a plurality of bit lines, where each word line is interconnected with each word line by a series combination of a phase-change device and an access device. In order to read or write to a phase-change device, the device must be selected by providing an appropriate electrical signal or combination of signals to the word line and bit line to which it is interconnected. The selection signal turns on the access device to permit current to flow through the phase-change device for reading or programming. In the non-selected state, the access device remains off and prevents current from reaching the phase-change device. In this way, the information stored in the phase-change device is preserved and not altered when other devices in the array are programmed.

In order to realize the multilevel programming benefits of the instant invention for devices in an array, it is necessary to include an access device that is capable of operating with both positive and negative polarity pulses. An access device that can be turned on (transformed to a state sufficiently conductive to enable current to flow to the phase-change device) with either a positive polarity or negative polarity signal may be referred to as a bi-directional access device. A representative bi-directional access device is the Ovonic threshold switch (OTS). The electrically-induced switching characteristics of OTS materials have been described in U.S. Pat. Nos. 5,543,737; 5,694,146; and 5,757,446; the disclosures of which are hereby incorporated by reference, as well as in several journal articles including “Reversible Electrical Switching Phenomena in Disordered Structures”, Physical Review Letters, vol. 21, p. 1450-1453 (1969) by S. R. Ovshinsky; “Amorphous Semiconductors for Switching, Memory, and Imaging Applications”, IEEE Transactions on Electron Devices, vol. ED-20, p. 91-105 (1973) by S. R. Ovshinsky and H. Fritzsche; the disclosures of which are hereby incorporated by reference. A discussion of using threshold switching materials as access devices in arrays is presented in U.S. patent application Ser. No. 12/070,682, the disclosure of which is incorporated by reference herein. A brief summary of the electrically-induced switching properties of a threshold switching material follows.

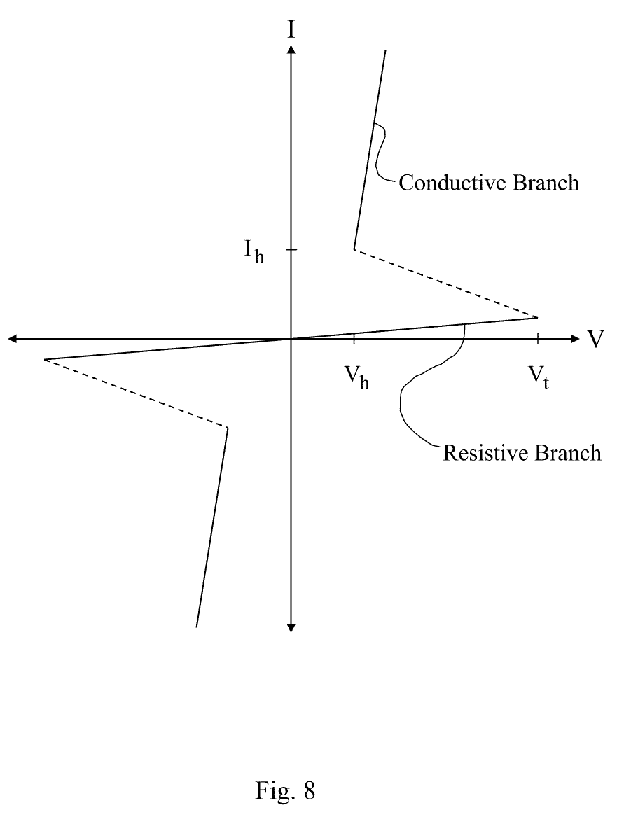

The electrically-induced switching properties of threshold switching materials are normally depicted in terms of the I-V (current-voltage) response of the material. The I-V response shows the current variation of a threshold switching material as a function of applied voltage. The I-V response of a switching material exhibits an electrically-induced switching event in which the material undergoes a transformation from a more resistive state to a more conductive state. A schematic depiction of the electrically-induced switching event is presented in FIG. 8. The depiction of FIG. 8 corresponds to a two-terminal device configuration in which two spacedly-disposed electrodes are in contact with a switching material. The I-V curve of FIG. 8 shows the current passing through the switching material as a function of the voltage applied across the material by the electrodes. The I-V characteristics of the material are generally symmetric with respect to the polarity of the applied voltage. For convenience, we consider the first quadrant of the I-V plot of FIG. 8 (the portion in which current and voltage are both positive) in the discussion of switching behavior that follows. An analogous description that accounts for polarity applies to the third quadrant of the I-V plot.

The I-V curve includes a resistive branch and a conductive branch. The branches are labeled in FIG. 8. The resistive branch corresponds to the regime in which the current passing through the material is a weak function of the applied voltage across the material. This branch exhibits a small slope in the I-V plot and appears as a nearly horizontal line in the first and third quadrants of FIG. 8. The conductive branch corresponds to the regime in which the current passing through the material is highly sensitive to the voltage applied across the material. This branch exhibits a large slope in the I-V plot and appears as a nearly vertical line in the first and third quadrants of FIG. 8. The slopes of the resistive and conductive branches shown in FIG. 8 are illustrative and not intended to be limiting, the actual slopes will depend on the chemical composition of the threshold switching material, device geometry, circuit configuration, and electrical contacts. Regardless of the actual slopes, the conductive branch exhibits a larger slope than the resistive branch. When device conditions are such that the switching material is described by a point on the resistive branch of the I-V curve, the switching material or device may be said to be in a resistive state. When device conditions are such that the switching material is described by a point on the conductive branch of the I-V curve, the switching material or device may be said to be in a conductive state.

In describing the electrically-induced switching properties of the material, we may first consider a device that has no voltage applied across it. When no voltage is applied across the switching material, the material is in a resistive state and no current flows through it. This condition corresponds to the origin of the I-V plot shown in FIG. 8. The switching material remains in a resistive state as the applied voltage is increased, up to a threshold voltage (labeled Vₜ in the first quadrant of FIG. 8). The slope of the I-V curve for applied voltages between 0 and Vₜ is small in magnitude, an indication that the material has a high electrical resistance. The high resistance implies low electrical conductivity and as a result, the current flowing through the material increases only weakly as the applied voltage is increased. Since the current through the material is very small, the resistive state of the threshold switching material may be referred to as the OFF state of the material.

When the applied voltage equals or exceeds the threshold voltage, the material transforms (switches) from the resistive branch to the conductive branch of the I-V curve. The switching event occurs essentially instantaneously and is depicted by the dashed line in FIG. 8. Upon switching, the device voltage decreases significantly and the device current becomes much more sensitive to changes in the device voltage. The switching material remains in the conductive branch as long as a minimum current, labeled Iₕ in FIG. 8, is maintained. We refer to Iₕ as the holding current and the associated voltage Vₕ as the holding voltage of the device. If the device conditions are changed so that the current becomes less than Iₕ, the material normally returns to the resistive branch of the I-V plot and requires subsequent application of a threshold voltage to resume operation on the conductive branch. If the current is only momentarily (a time less than the recovery time of the switching material) reduced below Iₕ, the conductive state of the switching material may be recovered upon restoring the current to or above Iₕ. The recovery time of chalcogenide switching materials has been discussed in the article “Amorphous Semiconductors for Switching, Memory, and Imaging Applications”, IEEE Transactions on Electron Devices, vol. ED-20, p. 91-105 (1973) by S. R. Ovshinsky and H. Fritzsche; the disclosure of which is incorporated by reference herein.

The foregoing discussion of the properties of the threshold switch indicates that it can serve as an access device in a dual polarity phase-change programming scheme. When the threshold switch is in its high resistance (OFF) state, it blocks access to a series-connected phase-change memory device. The high resistance state of the threshold switch prevents interactions of currents in the array with the interconnected phase-change device, a function that serves to maintain the integrity of information stored in the phase-change device. The threshold device is kept in the high resistance state when the phase-change device is non-selected. When the phase-change device is selected (by applying signals to the word line and bit line between which the series combination of the threshold switch and memory device are connected), the selection signals cause the voltage across the threshold switch to reach the threshold voltage to induce switching. Upon switching, the threshold switch transforms to its low resistance state and allows current to flow to and through the phase-change device to accomplish reading or programming.

Those skilled in the art will appreciate that the methods and designs described above have additional applications and that the relevant applications are not limited to those specifically recited above. Also, the present invention may be embodied in other specific forms without departing from the essential characteristics as described herein. The embodiments described above are to be considered in all respects as illustrative only and not restrictive in any manner.

We claim:

1. A method of programming a memory device comprising:
providing a memory device, said memory device operable over a plurality of memory states, said memory states being distinguishable on the basis of a physical property, said memory states including a first memory state associated with a first value of said physical property, a second memory state associated with a second value of said physical property, said second value exceeding said first value, and a third memory state associated with a third value of said physical property, said third value exceeding said second value;
applying a first electrical pulse to said memory device, said first electrical pulse having a first polarity and transforming said memory device to said first memory state;
applying a second electrical pulse to said memory device, said second electrical pulse having a second polarity and transforming said memory device to said second memory state; and
applying a third electrical pulse to said memory device, said third electrical pulse transforming said memory device to said third memory state.

2. The method of claim 1, wherein said memory device is a non-volatile memory device.

3. The method of claim 1, wherein said physical property is electrical resistance.

4. The method of claim 1, wherein said physical property is the strength or orientation of a magnetic moment.

5. The method of claim 1, wherein said first polarity is positive polarity and said second polarity is negative polarity.

6. The method of claim 1, wherein said third electrical pulse has said first polarity.

7. The method of claim 1, wherein the voltage of said first electrical pulse differs from the voltage of said second electrical pulse.

8. The method of claim 7, wherein the voltage of said third electrical pulse differs from the voltage of said first electrical pulse and the voltage of said second electrical pulse.

9. The method of claim 1, wherein the duration of said first electrical pulse differs from the duration of said second electrical pulse.

10. The method of claim 9, wherein the duration of said third electrical pulse differs from the duration of said first electrical pulse and the duration of said second electrical pulse.

11. The method of claim 1, wherein said memory device is a phase-change memory device, said phase-change memory device comprising a phase-change material, said phase-change material having a plurality of structural states, said first memory state, said second memory state, and said third memory state being selected from said structural states.

12. The method of claim 11, wherein said physical property corresponds to the resistance of said structural states.

13. The method of claim 12, wherein said structural states include a set state having a set resistance, a reset state having a reset resistance, and an intermediate state having a resistance between said set resistance and said reset resistance.

14. The method of claim 13, wherein said first memory state is said set state.

15. The method of claim 13, wherein said third memory state is said reset state.

16. The method of claim 15, wherein said first memory state is said set state.

17. The method of claim 16, wherein said third electrical pulse has said second polarity.

18. The method of claim 13, wherein the resistance of said third memory state is less than said reset resistance.

19. The method of claim 18, wherein said first memory state is said set state.

20. The method of claim 19, further comprising applying a fourth electrical pulse, said fourth electrical pulse programming said phase-change memory device to said reset state.

21. The method of claim 20, wherein said third electrical pulse has said first polarity and said fourth electrical pulse has said second polarity.

22. A method of programming a memory device comprising:
providing a memory device, said memory device operable over a plurality of memory states, said memory states being distinguishable on the basis of a physical property, said memory states including a first memory state associated with a first value of said physical property, a second memory state associated with a second value of said physical property, said second value exceeding said first value, a third memory state associated with a third value of said physical property, said third value exceeding said second value, and a fourth memory state associated with a fourth value of said physical property, said fourth value exceeding said third value.
applying a first electrical pulse to said memory device, said first electrical pulse having a first polarity and transforming said memory device to said second memory state;
applying a second electrical pulse to said memory device, said second electrical pulse having a second polarity and transforming said memory device to said third memory state.

23. The method of claim 22, wherein said physical property is electrical resistance.

24. The method of claim 22, wherein said memory device is a phase-change memory device, said phase-change memory device comprising a phase-change material, said phase-change material having a plurality of structural states, said first memory state, said second memory state, and said third memory state being selected from said structural states.

25. The method of claim 24, wherein said physical property corresponds to the resistance of said structural states.

26. The method of claim 25, wherein said structural states include a set state having a set resistance, a reset state having a reset resistance, and an intermediate state having a resistance between said set resistance and said reset resistance.

27. The method of claim 26, wherein said first memory state is said set state.

28. The method of claim 26, wherein said fourth memory state is said reset state.

29. The method of claim 28, wherein said first memory state is said set state.
